(19) United States
(12) Patent Application Publication
(10) Pub. No.: US 2025/0381727 A1
(43) Pub. Date: Dec. 18, 2025

(54) IMPRINT APPARATUS AND ARTICLE MANUFACTURING METHOD

(71) Applicant: CANON KABUSHIKI KAISHA, Tokyo (JP)

(72) Inventor: NAOKI MURASATO, Tochigi (JP)

(21) Appl. No.: 19/233,342

(22) Filed: Jun. 10, 2025

(30) Foreign Application Priority Data
Jun. 13, 2024 (JP) 2024-096263

(51) Int. Cl. B29C 59/02; B29C 59/00

(52) U.S. Cl. CPC B29C 59/022; B29C 59/002

(57) ABSTRACT

An imprint apparatus for forming a pattern on an imprint material on a substrate using a mold, includes a holder configured to hold the mold, and a deformation mechanism configured to deform the mold by applying a force to a side surface of the mold held by the holder, wherein the deformation mechanism includes an actuator, a first member driven by the actuator, and a second member configured to press the side surface of the mold along with driving of the first member by the actuator.

### BACKGROUND

### Field of the Technology

The present disclosure relates to an imprint apparatus and an article manufacturing method.

### Description of the Related Art

As an apparatus for manufacturing a fine structure device, there exists an imprint apparatus that molds an imprint material on a substrate using a mold. The imprint apparatus can include a mold deformation mechanism that corrects the shape of a pattern formed on the mold by pressing the side surfaces of the mold held by a mold holder and thus deforming the mold (for example, Japanese Patent Laid-Open No. 2008-504141).

The external dimensions of a mold can have individual differences. The difference of the external dimensions of the mold influences the stroke of a pressing member in the mold deformation mechanism or the amount of a force applied to the side surfaces of the mold. With this influence, an alignment error may increase.

### SUMMARY

The present disclosure provides a technique advantageous for accurately correcting the shape of a pattern formed on a mold without being influenced by the individual difference of the external dimensions of the mold.

The present disclosure in its one aspect provides an imprint apparatus for forming a pattern on an imprint material on a substrate using a mold, including a holder configured to hold the mold, and a deformation mechanism configured to deform the mold by applying a force to a side surface of the mold held by the holder, wherein the deformation mechanism includes an actuator, a first member driven by the actuator, and a second member configured to press the side surface of the mold along with driving of the first member by the actuator.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing the configuration of an imprint apparatus;

FIG. 2 is a sectional view showing the detailed configuration of an imprint head;

FIG. 3 is a bottom view of the imprint head;

FIG. 4 is a view showing the detailed configuration of a mold deformation mechanism;

FIGS. 5A to 5C are views showing the configuration of a connecting portion;

FIGS. 6A to 6C are views showing the configuration of the connecting portion;

FIGS. 7A to 7D are views for explaining an example of the operation of the mold deformation mechanism;

FIG. 8 is a view for explaining, for each mold size, the relationship between a driving source output and a force applied to a mold;

FIGS. 9A and 9B are views showing the detailed configuration of the mold deformation mechanism according to a modification;

FIG. 10 is a view showing the detailed configuration of the mold deformation mechanism;

FIG. 11 is a view for explaining, for each distance between the distal end of a driving transmission portion and a side surface of a mold, the relationship between a driving source output and a force applied to the mold; and

FIG. 12 is a view for explaining an article manufacturing method according to the embodiment.

### DESCRIPTION OF THE EMBODIMENTS

Hereinafter, embodiments will be described in detail with reference to the attached drawings. Note, the following embodiments are not intended to limit the scope of the claimed disclosure. Multiple features are described in the embodiments, but limitation is not made to a disclosure that requires all such features, and multiple such features may be combined as appropriate. Furthermore, in the attached drawings, the same reference numerals are given to the same or similar configurations, and redundant description thereof is omitted.

The configuration of an imprint apparatus will now be described with reference to the accompanying drawings. In this specification and the accompanying drawings, directions are indicated on an XYZ coordinate system in which a horizontal plane is defined as an XY plane. In general, a substrate is placed on a substrate stage such that its surface is parallel to the horizontal plane (XY plane). Hence, directions orthogonal to each other in a plane along the surface of the substrate will be defined as the X-axis and the Y-axis hereinafter, and a direction perpendicular to the X-axis and the Y-axis will be defined as the Z-axis. Also, directions parallel to the X-axis, the Y-axis, and the Z-axis in the XYZ coordinate system will be defined as the X direction, the Y direction, and the Z direction, respectively, hereinafter, and a rotation direction about the X-axis, a rotation direction about the Y-axis, and a rotation direction about the Z-axis will be defined as the θX direction, the θY direction, and the θZ direction, respectively.

The outline of an imprint apparatus according to the embodiment will be described first. The imprint apparatus is an apparatus that brings an imprint material supplied onto a substrate into contact with a mold, and applies curing energy to the imprint material, thereby forming a pattern of a cured product to which the concave-convex pattern of the mold is transferred.

As the imprint material, a curable composition (to be also referred to as a resin in an uncured state) to be cured by receiving curing energy is used. As the curing energy, an electromagnetic wave, heat, or the like can be used. The electromagnetic wave can be, for example, light whose wavelength is selected from the range of 10 nm or more to 1 mm or less, for example, infrared rays, visible light, ultraviolet rays, and the like. The curable composition can be a composition cured by light irradiation or heating. A photocurable composition cured by light irradiation contains at least a polymerizable compound and a photopolymerization initiator, and may further contain a nonpolymerizable compound or a solvent, as needed. The nonpolymerizable compound is at least one type of material selected from the group consisting of a sensitizer, a hydrogen donor, an internal mold release agent, a surfactant, an antioxidant, a polymer component, and the like. The imprint material can be arranged on a substrate in a droplet shape or in an island or film shape formed by connecting a plurality of droplets using an imprint material supply device (dispenser). The viscosity (the viscosity at 25°C) of the imprint material can be, for example, 1 mPa⋅s or more to 100 mPa⋅s or less. As the material of the substrate, for example, glass, ceramic, a metal, a semiconductor, a resin, or the like can be used. A member made of a material different from that of the substrate may be provided on the surface of the substrate, as needed. The substrate is, for example, a silicon wafer, a semiconductor compound wafer, or silica glass.

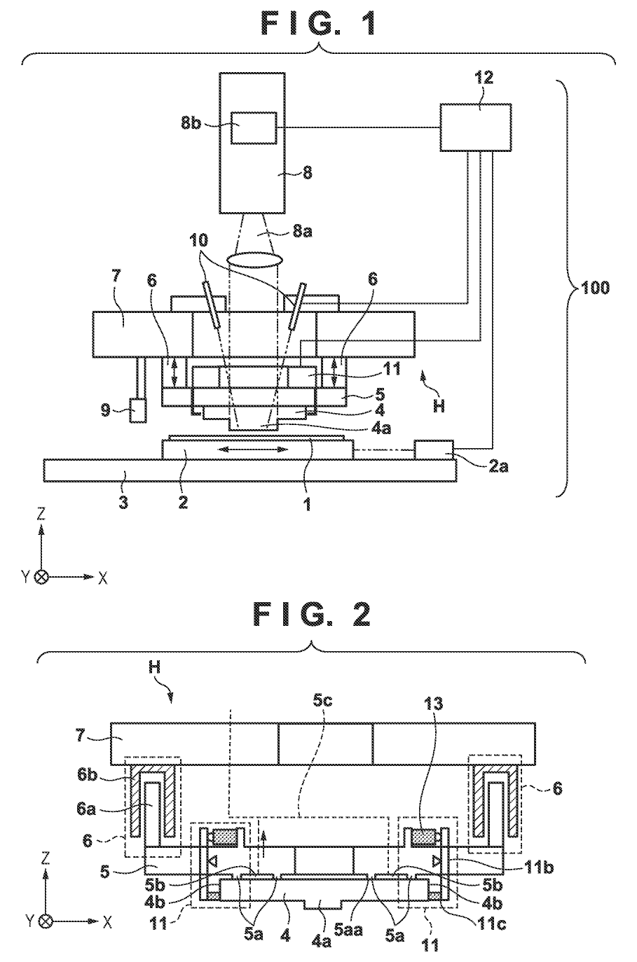

FIG. 1 is a view showing an example of the configuration of an imprint apparatus 100 according to the embodiment. The imprint apparatus 100 is configured to repeat an imprint cycle, thereby forming a pattern on a plurality of shot regions of a substrate. By transferring the pattern of a mold 4 to a substrate 1, an element pattern corresponding to the pattern of the mold is formed on the substrate surface layer. A substrate stage 2 that holds the substrate 1 is arranged on a base 3. The substrate stage 2 can move on the base 3 while being guided by the base 3. When the substrate stage 2 moves, the substrate 1 moves. A controller 12 can move the substrate 1 to an imprint region under the mold 4 by moving the substrate stage 2 in the X and Y directions and the θZ direction. A displacement sensor 2a that detects the movement position of the substrate stage 2 is arranged on the base 3. The displacement sensor 2a can be formed by a laser interferometer or an encoder. The controller 12 drives the motor of the substrate stage 2 based on the detection value of the displacement sensor 2a, thereby accurately positioning the substrate 1.

The mold 4 includes a mesa 4a that is a plateau-shaped portion. A concave-convex pattern is formed on the surface of the mesa 4a. When the surface of the mesa 4a is brought into contact with the imprint material supplied onto the substrate 1, the pattern is transferred to the imprint material on the substrate 1. The mesa 4a has a step shape projecting downward to prevent a region of the mold 4 other than the mesa 4a from contacting the substrate 1 or the imprint material thereon.

The imprint apparatus 100 includes an imprint head H that is a mechanism configured to hold and move the mold 4. The imprint head H can include a mold holder 5 (holder) that holds the mold 4, a driving mechanism 6 configured to drive the mold holder 5 (that is, the mold 4) in the Z direction, and a mold deformation mechanism 11 (deformation mechanism) that deforms the mold 4 by applying a force to the side surfaces of the mold 4 held by the mold holder 5. The mold holder 5 can hold the mold 4 by vacuum suction or electrostatic attraction. The detailed configuration of the imprint head H will be described later with reference to FIG. 2. Here, the mold holder 5 holds the mold 4 by vacuum suction. The driving mechanism 6 is fixed to a frame 7. By the driving mechanism 6, operations of bringing the mold 4 into contact with the imprint material on the substrate 1 and separating the mold 4 from the imprint material on the substrate 1 can be performed.

A curing device 8 cures the imprint material by irradiating the imprint material on the substrate 1 with ultraviolet light 8a through the mold 4. The curing device 8 can include a shutter 8b configured to control the irradiation timing of the ultraviolet light 8a.

The frame 7 is provided with a dispenser 9 that supplies the imprint material. After the substrate 1 is moved by the substrate stage 2 such that a shot region of the substrate 1 is located under the dispenser 9, the dispenser 9 supplies the imprint material onto the shot region. During an imprint step, the substrate stage 2 reciprocally moves between under the dispenser 9 and under the mold 4. Note that the dispenser 9 need not always provided in the imprint apparatus 100. For example, the imprint step may be performed by locating, under the mold 4, a substrate with an imprint material applied to the whole surface in advance outside the apparatus and repeating an imprint operation and step movement at a pitch according to the shot region size. In this case, since a dispensing step can be omitted, productivity can be improved.

A scope 10 includes an optical lens, an illumination unit, and an image capturing unit inside, and detects a relative position deviation between an alignment mark of the mold 4 and an alignment mark of the substrate 1. The substrate stage 2 is moved by an amount corresponding to the deviation amount, thereby performing alignment between the mold 4 and the substrate 1.

The controller 12 is electrically connected to the above-described units and controls the units, thereby executing processing associated with imprint. Here, the controller 12 can perform optimum alignment control based on the alignment information of the scope 10, the position information of the substrate stage 2, and the information of a load that the mold deformation mechanism 11 applies to the mold 4.

FIG. 2 is a sectional view showing the detailed configuration of the imprint head H. The back surface of the mold 4 and the mold holder 5 come into contact with contact surfaces 5aa that are the bottom surfaces of attraction projecting portions 5a. If the mold 4 and bottom surfaces of the attraction projecting portion 5a come into contact with each other, a region 5b that is a closed space surrounded by the mold 4 and the attraction projecting portions 5a is formed. A vacuum pipe 5c is connected to the region 5b. When the region 5b is evacuated, the mold holder 5 can chuck the mold 4. The mold holder 5 is supported by the frame 7 via the driving mechanism 6. The driving mechanism 6 can include a fixed portion 6b fixed to the frame, and a movable portion 6a that is fixed to the mold holder 5 and moves with respect to the fixed portion 6b. For example, the driving mechanism 6 can include a voice coil motor or a linear shaft motor. No frictional portion exists between the fixed portion 6b and the movable portion 6a, and this is advantageous against foreign substance generation risk. However, for the driving mechanism 6, a driving source that has frictional portions and takes foreign substance attraction measure, for example, a rotation motor of a ball screw, an air cylinder, or a piezoelectric element actuator may be used.

The mold deformation mechanism 11 includes an actuator 13 that is a driving source, and a driving transmission portion 11b, and can deform the mold 4 by giving a desired force to side surfaces 4b of the mold 4 to correct the shape of the pattern formed on the mold 4. Also, the mold deformation mechanism 11 can further include a load cell 11c that is a force sensor for measuring the force given to the side surfaces 4b of the mold 4. A force generated by the actuator 13 is converted by the driving transmission portions 11b based on the principle of leverage and applied to the side surfaces 4b of the mold 4 via the load cells 11c. This structure is advantageous because it can adjust the amounts of the force generated by the actuator 13 and the force to be actually applied to the mold 4 by the fulcrum position of the driving transmission portion 11b. Also, as for the arrangement of the actuator 13, the actuator 13 can be placed on the upper surface of the mold holder 5 where a relatively large space exists. The detailed structure of the mold deformation mechanism 11 will be described later.

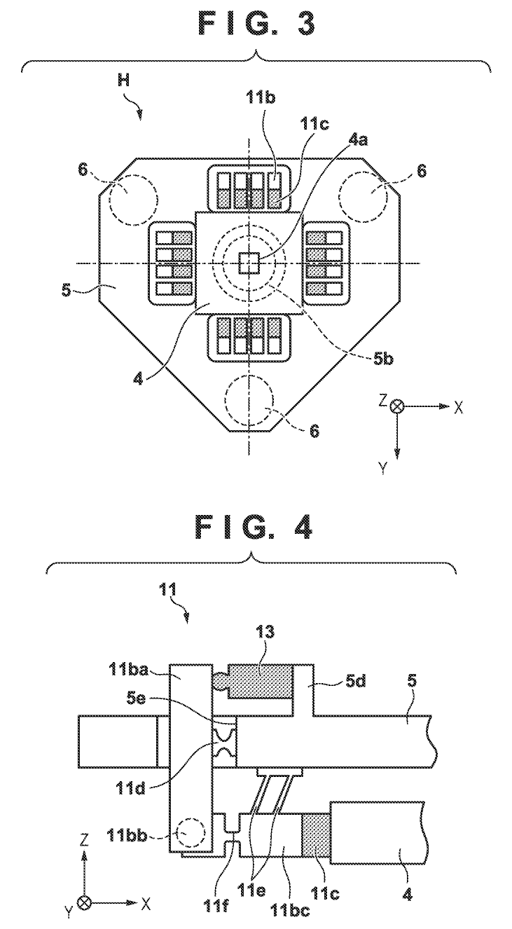

FIG. 3 is a bottom view of the imprint head H. As shown in FIG. 3, the driving mechanisms 6 are arranged at three points around the mold 4. The region 5b exists on the back surface side of the mold 4, and the mold 4 is sucked and held by evacuating the region 5b.

The driving transmission portions 11b and the load cells 11c of the mold deformation mechanism 11 are arranged in each of penetration regions of the mold holder 5 formed in correspondence with the sides of the mold 4. In the example shown in FIG. 3, four driving transmission portions 11b and four load cells 11c are evenly arranged on each side surface of the mold 4. That is, in the imprint head H, 16 driving transmission portions 11b and 16 load cells 11c are used. The number of driving transmission portions 11b and load cells 11c can be decided in accordance with the size of the mold 4 and an assumed deformation shape or correction amount. Although not illustrated, a sensor such as a laser interferometer configured to measure the size or arrangement of the mold may be arranged around the mold 4.

FIG. 10 is a view showing an example of the detailed configuration of the mold deformation mechanism 11. The actuator 13 is arranged above the mold holder 5. In an example, the base-side end portion of the actuator 13 is fixed to a flange 5d formed on the mold holder 5, and the actuator 13 is driven in the X direction (first direction) parallel to the contact surface 5aa. The driving transmission portion 11b is connected, at its one end, to the output end of the actuator 13 via a bearing (not shown). The actuator 13 applies a force to the driving transmission portion 11b in accordance with an instruction value from the controller 12. The actuator 13 is preferably formed by a piezoelectric element actuator that can perform high output in a small space, but an actuator such as an air cylinder or an ultrasonic motor may be used.

The driving transmission portion 11b can convert, using a fulcrum portion 11d as a fulcrum, a force applied in the -X direction by the actuator 13 into a force toward the +X direction in which the side surface 4b of the mold 4 exists. A parallel spring 11e is formed between the mold holder 5 and the driving transmission portion 11b. The parallel spring 11e can elastically be deformed in the X direction (first direction) parallel to the contact surface 5aa, and has a role of guiding the driving transmission portion 11b such that it accurately moves in the X direction.

The load cell 11c can be arranged at the distal end of the driving transmission portion 11b on the side of the mold 4. In this case, the driving transmission portion 11b presses the side surface 4b of the mold 4 via the load cell 11c. The load cell 11c detects the force of the driving transmission portion 11b pressing the mold 4. Intervention of the load cell 11c between the distal end of the driving transmission portion 11b and the mold 4 is not essential, but to reduce detection errors, the load cell 11c is preferably arranged closer to the mold side with respect to the parallel spring 11e. Hereinafter, both "the driving transmission portion 11b presses the side surface 4b of the mold 4 via the load cell 11c" and "the driving transmission portion 11b directly presses the side surface 4b of the mold 4" will be expressed as "the driving transmission portion 11b presses the side surface 4b of the mold 4" for the sake of convenience. Similarly, both "the driving transmission portion 11b contacts the side surface 4b of the mold 4 via the load cell 11c" and "the driving transmission portion 11b directly contacts the side surface 4b of the mold 4" will be expressed as "the driving transmission portion 11b contacts the side surface 4b of the mold 4" for the sake of convenience.

Also, not illustrated for the sake of simplicity, another parallel spring or a hinge portion may be formed on the driving transmission portion 11b. Also, an avoiding portion 11f is formed or arranged on the driving transmission portion 11b. The avoiding portion 11f is configured to absorb a distortion or position deviation of the driving transmission portion 11b in a direction parallel to the side surface 4b of the mold 4.

FIG. 10 shows that in a state in which the output of the actuator 13 is zero, the load cell 11c arranged at the distal end of the driving transmission portion 11b is not in contact with the side surface of the mold 4, and there exists a space. This space is an extra space provided in consideration of the individual difference of the outer shape of the mold and/or in consideration of insertion of the mold into a region surrounded by a plurality of driving transmission portions 11b (or load cells 11c).

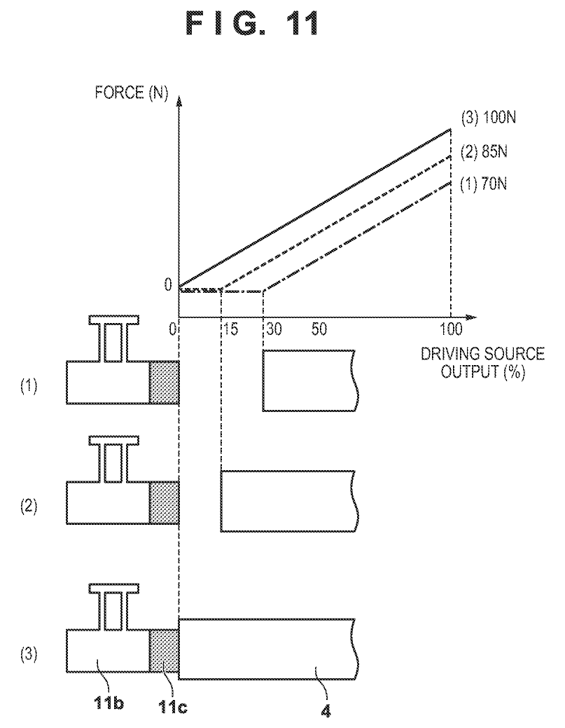

FIG. 11 is a graph showing, for each distance between the distal end of the driving transmission portion 11b and the side surface of the mold 4, the relationship between the output (driving source output) of the actuator 13 and the force applied to the mold 4. In FIG. 11, the abscissa indicates the driving source output (%), and the ordinate indicates a force (N) applicable to the mold 4. The distance between the load cell 11c and the side surface 4b of the mold 4 when the driving source output is zero changes between states (1), (2), and (3). The relationship of the distances is given by (1) > (2) > (3). In the state (1), that is, in a case where the distance is large, a large driving source output (here, about 30%) needs to be consumed until the force begins to be applied to the mold 4, and as a result, at the time of 100% output, only 70 N is applied to the mold 4 at maximum. On the other hand, in the state (3), that is, in a case where the distance is almost zero, it is possible to start applying the force to the mold 4 with a driving source output of almost zero. For this reason, when the output is 100%, about 100 N can be applied to the mold 4 at maximum. The distance changes depending on the individual difference of the external dimensions of the mold 4 or a placement error of the mold 4. Hence, considering the error as well, the arrangement of the mold deformation mechanism is decided such that the distance is in the intermediate state (2) when the mold has an average size. Since the actual mold size has an error range to attain the states (1) to (3), the maximum force applicable to the mold also has an error in the range of 70 to 100 N. Since the driving source output is limited, to apply a force as large as possible to the mold, the error of the mold size exerts an influence. Thus, the force applicable to the mold may be short due to the influence of the error of the mold size.

FIG. 4 is a view showing an example of the detailed configuration of the mold deformation mechanism 11 to solve the above-described problem. In FIG. 4, the actuator 13 is arranged above the mold holder 5. In an example, the base-side end portion of the actuator 13 is fixed to the flange 5d formed on the mold holder 5, and the actuator 13 is driven in the X direction (first direction) parallel to the contact surface 5aa.

In FIG. 4, the driving transmission portion (corresponding to the driving transmission portion 11b in FIG. 10) is separated to a lever transmission portion 11ba (first member) and a horizontal transmission portion 11bc (second member). The lever transmission portion 11ba extends in the second direction (for example, the Y direction) crossing the contact surface 5aa, and is connected to the output end of the actuator 13 at one end portion and connected to the horizontal transmission portion 11bc via connecting portions 11bb at the other end portion. The horizontal transmission portion 11bc extends in the X direction (first direction) on the lower side of the mold holder 5, and is connected to the lever transmission portion 11ba via the connecting portions 11bb at one end portion and configured to press the side surface 4b of the mold 4 on the other end side.

The mold deformation mechanism 11 can include the fulcrum portion 11d arranged on a wall surface 5e crossing the contact surface 5aa. The lever transmission portion 11ba swings with respect to the fulcrum portion 11d as a fulcrum in accordance with the driving of the actuator 13. The lever transmission portion 11ba can convert, using the fulcrum portion 11d as a fulcrum, a force applied in the -X direction by the actuator 13 into a force toward the +X direction in which the side surface 4b of the mold 4 exists. The parallel spring 11e is formed between the mold holder 5 and the horizontal transmission portion 11bc. The parallel spring 11e can elastically be deformed in the X direction (first direction) parallel to the contact surface 5aa, and has a role of guiding the horizontal transmission portion 11bc such that it accurately moves in the X direction.

The load cell 11c can be arranged at the distal end of the horizontal transmission portion 11bc on the side of the mold 4. In this case, the horizontal transmission portion 11bc presses the side surface 4b of the mold 4 via the load cell 11c. The load cell 11c detects the force of the horizontal transmission portion 11bc pressing the mold 4. Intervention of the load cell 11c between the distal end of the horizontal transmission portion 11bc and the mold 4 is not essential, but to reduce detection errors, the load cell 11c is preferably arranged closer to the mold side with respect to the parallel spring 11e. Hereinafter, both "the horizontal transmission portion 11bc presses the side surface 4b of the mold 4 via the load cell 11c" and "the horizontal transmission portion 11bc directly presses the side surface 4b of the mold 4" will be expressed as "the horizontal transmission portion 11bc presses the side surface 4b of the mold 4" for the sake of convenience. Similarly, both "the horizontal transmission portion 11bc contacts the side surface 4b of the mold 4 via the load cell 11c" and "the horizontal transmission portion 11bc directly contacts the side surface 4b of the mold 4" will be expressed as "the horizontal transmission portion 11bc contacts the side surface 4b of the mold 4" for the sake of convenience.

Also, the avoiding portion 11f is formed or arranged on the horizontal transmission portion 11bc. The avoiding portion 11f is configured to absorb a distortion or position deviation of the driving transmission portion 11b in a direction parallel to the side surface 4b of the mold 4.

In this embodiment, the mold deformation mechanism 11 is configured to be able to adjust the positional relationship between the lever transmission portion 11ba and the horizontal transmission portion 11bc. For example, the lever transmission portion 11ba and the horizontal transmission portion 11bc are connected by the connecting portions 11bb. The connecting portions 11bb are configured to be able to switch between a connected state in which the lever transmission portion 11ba and the horizontal transmission portion 11bc are connected and a nonconnected state in which the lever transmission portion 11ba and the horizontal transmission portion 11bc are not connected. At this time, the connecting portions 11bb can switch the lever transmission portion 11ba and the horizontal transmission portion 11bc at an arbitrary angle between the connected state and the nonconnected state. By switching between the connected state and the nonconnected state in accordance with the driving source output, the position to start moving the horizontal transmission portion 11bc and the position where the force is applied to the mold 4 can be adjusted.

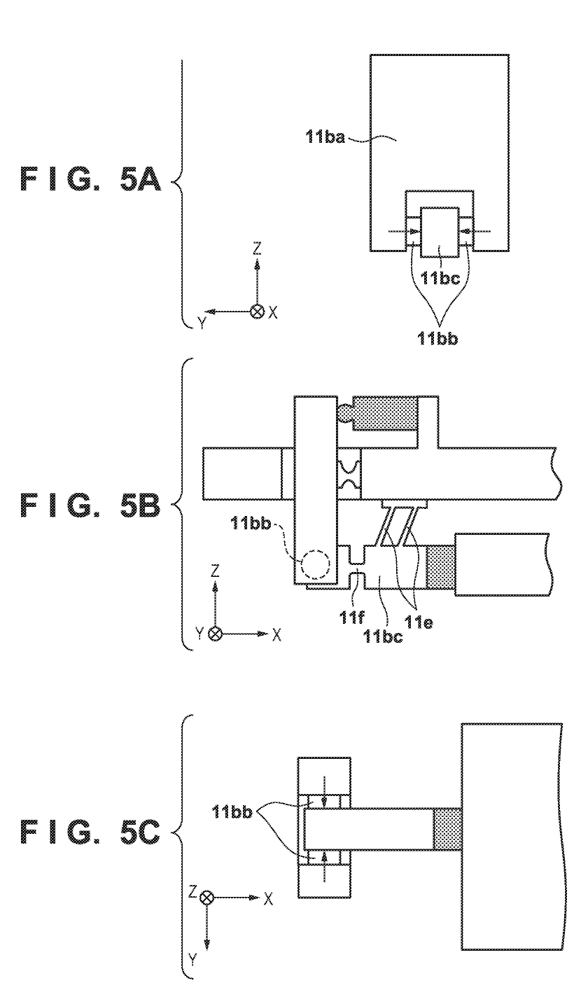

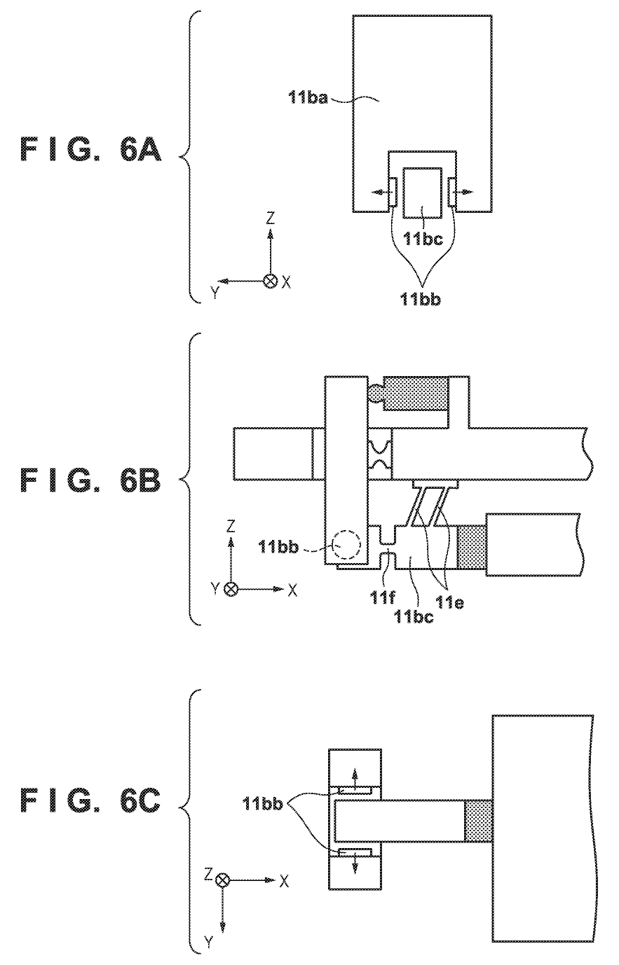

An example of the configuration of the above-described connecting portions 11bb that switch between the connected state and the nonconnected state will be described with reference to FIGS. 5A to 5C and FIGS. 6A to 6C. FIG. 5A is a side view of the mold deformation mechanism 11 viewed from the X direction. FIG. 5B is a side view of the mold deformation mechanism 11 viewed from the Y direction and is the same as FIG. 4. FIG. 5C is a bottom view of the mold deformation mechanism 11 viewed from below in the Z direction. The connected state is a state in which when the actuator 13 is driven, the lever transmission portion 11ba and the horizontal transmission portion 11bc can interlockingly press the side surface 4b of the mold 4. On the other hand, the nonconnected state is a state in which drive of the lever transmission portion 11ba by the actuator 13 does not act on the horizontal transmission portion 11bc, and it is impossible to press the side surface 4b of the mold 4.

As shown in FIG. 5A, a notch portion is formed at the lower end of the lever transmission portion 11ba, and in the notch portion, the end portion of the horizontal transmission portion 11bc is sandwiched by the connecting portions 11bb (connected state). When the end portion is sandwiched from the direction (Y direction) vertical to the moving direction (X direction) of the parallel spring 11e of the horizontal transmission portion 11bc, the transmission portions can be connected at an arbitrary position regardless of the movement position in driving of the horizontal transmission portion 11bc. The connected state is a state in which even if the force is applied to the side surface 4b of the mold 4 held by the mold holder 5 in accordance with the driving source output, no position deviation occurs between the lever transmission portion 11ba and the horizontal transmission portion 11bc. For example, if the amount of the force applied to the mold 4 is 100 N at maximum, a friction force necessary for connection is 100 N or more, and the friction coefficient is 0.1, a force necessary for connection is 1,000 N. The force to connect can be created by converting the force based on the principle of leverage using the expansion force of a pneumatic or hydraulic cylinder or piezoelectric element. Also, a lateral deviation prevention effect may be improved by providing a gradient on the contact surface of the connecting portion 11bb and ensuring a large friction function.

FIGS. 6A to 6C show a state (nonconnected state) in which the lever transmission portion 11ba and the horizontal transmission portion 11bc are not connected by the connecting portions 11bb. FIG. 6A is a side view of the mold deformation mechanism 11 viewed from the X direction. FIG. 6B is a side view of the mold deformation mechanism 11 viewed from the Y direction and is the same as FIG. 4. FIG. 6C is a bottom view of the mold deformation mechanism 11 viewed from below in the Z direction. When the connecting portions 11bb are operated to be separated from the horizontal transmission portion 11bc, gaps are formed between the connecting portions 11bb and the horizontal transmission portion 11bc, and a nonconnected state is obtained. In the nonconnected state, even if the driving source output is changed, the force is not transmitted to the horizontal transmission portion 11bc, and no action on the mold 4 occurs.

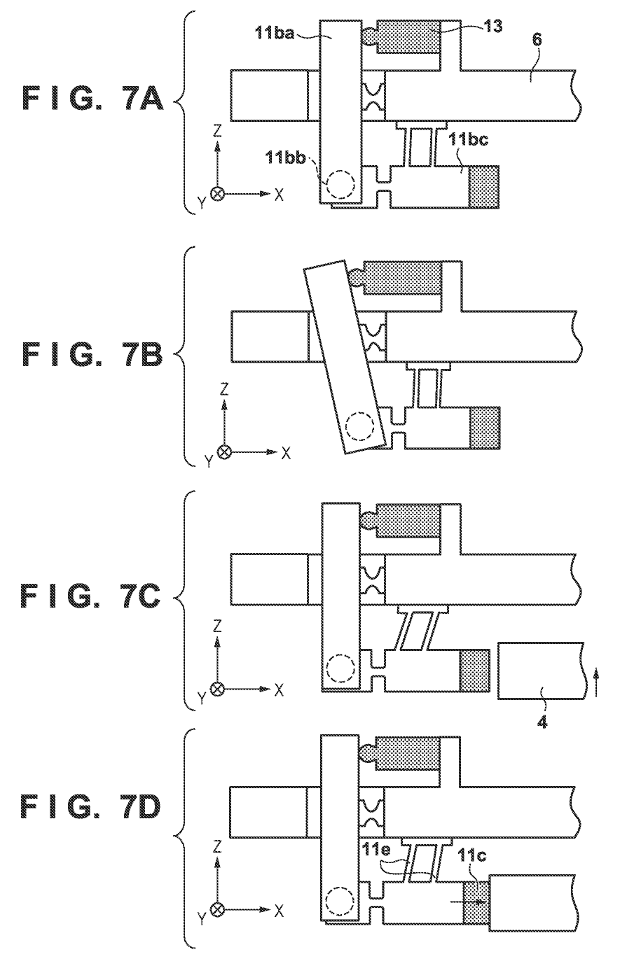

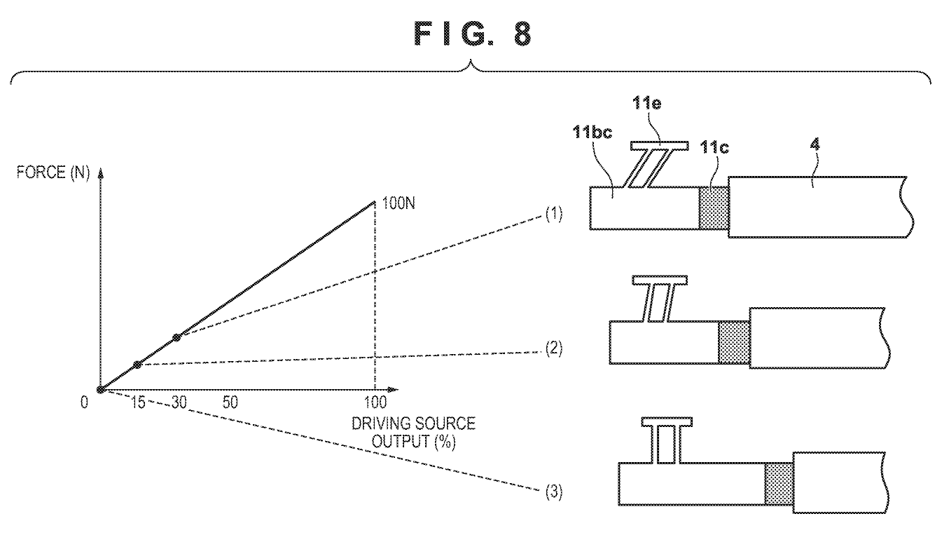

The controller 12 controls the actuator 13 and the connecting portions 11bb. An example of the operation of the mold deformation mechanism 11 (including control of the actuator 13 and the connecting portions 11bb by the controller 12) will be described with reference to FIGS. 7A to 7D. When the output of the actuator 13 is an initial value (for example, zero or a value close to zero) (first value), the controller 12 controls the actuator 13 and the connecting portions 11bb such that the horizontal transmission portion 11bc contacts the side surface 4b of the mold 4.

FIGS. 7A to 7D show a procedure from a preparation step before the mold 4 is inserted into the region surrounded by the plurality of driving transmission portions 11b (or load cells 11c) until the mold 4 is inserted and mold deformation driving is started. In FIG. 7A, the mold 4 is not loaded yet, and the driving source output is the initial value (for example, zero) (first value). Also, the connecting portions 11bb are in the nonconnected state, and therefore, no force is applied to the horizontal transmission portion 11bc.

In the state shown in FIG. 7A, the controller 12 sets the output of the actuator 13 to a second value (for example, 100% or a value close to 100%) larger than the first value and drives the lever transmission portion 11ba. In a state in which the lever transmission portion 11ba is completely moved, the controller 12 switches the connecting portions 11bb to the connected state. Thus, the lever transmission portion 11ba and the horizontal transmission portion 11bc are connected. FIG. 7B shows this state.

Next, the controller 12 returns the driving source output to the initial value. Thus, the actuator 13 and the lever transmission portion 11ba return to the original positions, and the horizontal transmission portion 11bc is pulled and moved in the direction opposite to the mold side. When the horizontal transmission portion 11bc moves, a clearance for inserting the mold 4 to a position under the mold holder 5 is ensured. The controller 12 controls a mold conveyance unit (not shown) to load the mold 4. FIG. 7C shows this state.

According to the processing up to this point, in the state shown in FIG. 7C, the driving source output is the initial value (first value), the horizontal transmission portion 11bc and the side surface 4b of the mold 4 is in the nonconnected state, and the connecting portions 11bb are in the connected state. In this state, the controller 12 increases the driving source output such that the horizontal transmission portion 11bc contacts the side surface 4b of the mold 4. If the contact to the side surface 4b of the mold 4 is detected by the load cells 11c, the controller 12 stops increasing the driving source output and maintains a constant output, thereby making the actuator 13 stay at that position. In this state, the controller 12 switches the connecting portions 11bb to the nonconnected state and returns the driving source output to the initial value (close to zero) again. After that, the controller 12 switches the connecting portions 11bb to the connected state. FIG. 7D shows this state. Every time the mold is changed, this state is set, and force application to the mold 4 can thus be started from a state in which the driving source output is close to zero in alignment during imprint processing.

When the mold deformation mechanism 11 is operated in accordance with this procedure, the output of the actuator 13 is not consumed until the driving transmission portion 11b contacts the mold 4, unlike the comparative example shown in FIG. 11. It is therefore possible to use the force in the whole range that the actuator 13 can generate for mold shape correction.

Also, the state shown in FIG. 7D at the start of mold deformation driving is a state in which a force is applied to the mold 4 in advance by the reaction force of deformation of the parallel spring 11e. Since this force can be detected by the load cell 11c, when setting the state shown in FIG. 7D, the connecting portions 11bb are switched to the connected state in a state in which the driving source output corresponding to the force is input in advance, thereby handling the reaction force of deformation of the parallel spring 11e. By this handling, the force applied to the mold when the driving source output is decreased to zero can be reduced to almost zero such that the force of the parallel spring 11e is canceled. An example of the operation at this time will be described with reference to FIG. 8.

FIG. 8 is a graph showing, for each mold size, the relationship between the driving source output and the force applied to the mold. The abscissa and the ordinate of FIG. 8 are the same as those of FIG. 11. The abscissa indicates the driving source output (%), and the ordinate indicates a force (N) applicable to the mold 4. Here, three molds of different sizes will be considered. The three mold sizes are defined as L, M, and S in descending order. Case (1) is a case where the mold of L size is used, case (2) is a case where the mold of M size is used, and case (3) is a case where the mold of S size is used.

In case (1), the mold size is larger than the remaining cases. For this reason, the displacement of the horizontal transmission portion 11bc in the direction opposite to the mold is large, and a large force is applied as a reaction force to the mold. As shown in FIG. 8, if the force is 30% as a driving source output value, when setting the state shown in FIG. 7D, the controller 12 switches the connecting portions 11bb to the connected state in a state in which an output of 30% is given to the driving source output in advance. Thus, when the driving source output is returned to zero, this acts in a direction of reducing the force to the mold by the same amount. As a result, by the driving source output operation in connected switching, the range of the force applied to the mold can be controlled in the whole range from minimum (almost 0 N) to maximum (for example, 100 N). Reversely, in case (3), since the mold size is small as compared to the remaining cases, the reaction force of the horizontal transmission portion 11bc to the mold is close to zero, and the driving source output at the time of connection can be started in a zero state. Case (2) is an intermediate state between case (1) and case (3), which have a substantially linear relationship, and in this example, the state can be switched to the connected state with a driving source output of 15%. As described above, in the example shown in FIG. 8, to eliminate the influence of the mold size difference between cases (1) to (3), the driving source output at the time of connection switching is changed in correspondence with the load cell output. It is therefore possible to use the force in the whole range (including 0 N) that the actuator 13 can generate for mold shape correction.

### (Modification)

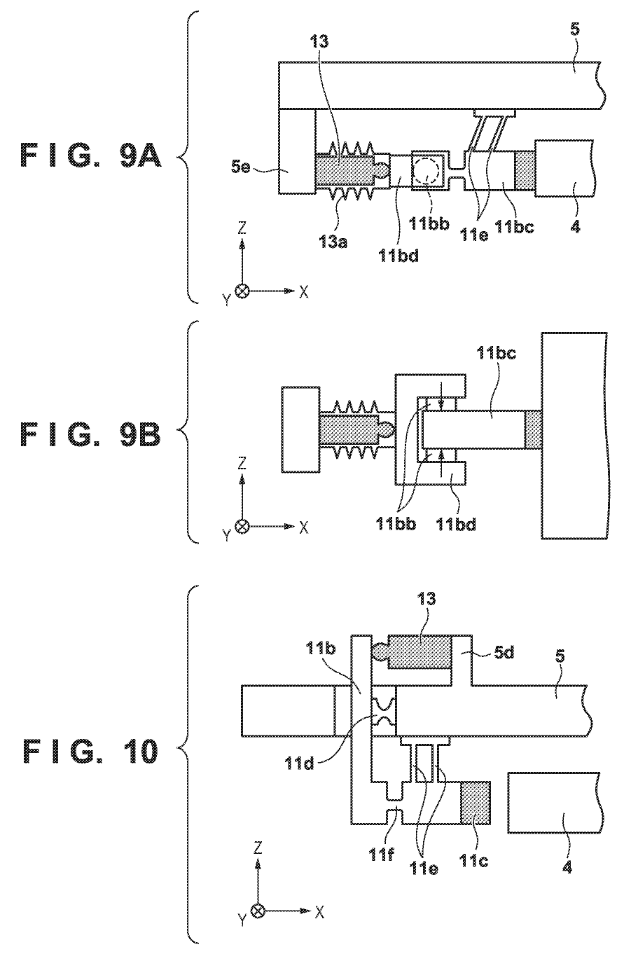

FIGS. 9A and 9B are views showing the detailed configuration of the mold deformation mechanism 11 according to a modification. FIG. 9A is a side view of the mold deformation mechanism 11 viewed from the Y direction, and FIG. 9B is a bottom view of the mold deformation mechanism 11 viewed from below in the Z direction.

The horizontal transmission portion 11bc, the parallel spring 11e, and the connecting portions 11bb are the same as the components shown in FIG. 4. In the example shown in FIGS. 9A and 9B, however, the driving force is transmitted not by the principle of leverage but by linear motion driving. More specifically, in FIGS. 9A and 9B, the lever transmission portion 11ba does not exist. Instead, a linear motion transmission portion 11bd is provided between the actuator 13 and the connecting portions 11bb. Hence, the mold deformation mechanism 11 forms a linear motion mechanism in which the actuator 13, the linear motion transmission portion 11bd (first member), the connecting portions 11bb, and the horizontal transmission portion 11bc (second member) are sequentially arranged in the first direction parallel to the contact surface 5aa toward the side surface 4b of the mold 4.

The base-side end portion of the actuator 13 is fixed to the flange 5d provided on the outer peripheral portion of the mold holder 5, and the output end of the actuator 13 is connected to the end portion of the linear motion transmission portion 11bd via a bearing (not shown). The connecting portions 11bb connect the linear motion transmission portion 11bd and the horizontal transmission portion 11bc.

In the example shown in FIGS. 9A and 9B, since no fulcrum portion exists, the displacement amount cannot be adjusted at the fulcrum position. Instead, a configuration in which the rigidity balance to the output of the actuator 13 is ensured using a compression spring 13a that expands/contracts in a direction parallel to the driving direction of the actuator 13 is employed. This can adjust the driving amount of the actuator 13 to a desired displacement stroke.

In the configuration according to this modification, the actuator 13 and the flange 5d to fix it need to be arranged on the outer peripheral portion of the mold holder 5. If the unit size of the entire imprint head can be made large, this configuration is advantageous because the structure of the transmission unit can be simplified. In the configuration according to the modification as well, it is possible to use the force in the whole range (including 0 N) that the actuator 13 can generate for mold shape correction.

### <Embodiment of Method of Manufacturing Article>

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as at least some of the constituent members of the above-described articles or used temporarily as a resist mask. After etching or ion implantation is performed in the substrate processing step, the resist mask is removed.

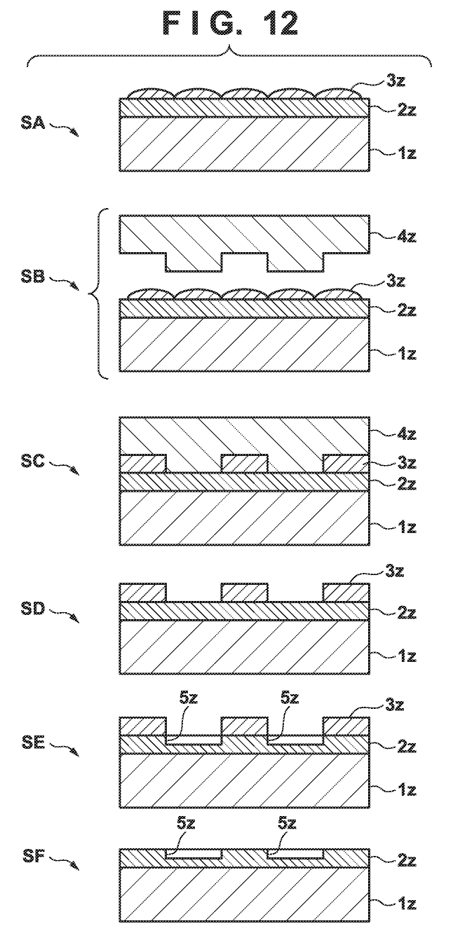

Referring to FIG. 12, a method of manufacturing an article will be described next. As shown step SA, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in step SB, a side of a mold 4z for imprint with an uneven pattern is directed toward and made to face the imprint material 3z on the substrate. As shown in step SC, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with energy for curing via the mold 4z, the imprint material 3z is cured.

As shown in step SD, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the uneven pattern of the mold 4z is transferred to the imprint material 3z.

As shown in step SE, when etching is performed using the pattern of the cured product as an etching resistant mask, a portion of the surface of the processed material 2z where the cured product does not exist or remains thin is removed to form a groove 5z. As shown in step SF, when the pattern of the cured product is removed, an article with the grooves 5z formed in the surface of the processed material 2z can be obtained. Here, the pattern of the cured product is removed. However, instead of processing or removing the pattern of the cured product, it may be used as, for example, an interlayer dielectric film included in a semiconductor element or the like, that is, a constituent member of an article.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-096263, filed June 13, 2024, which is hereby incorporated by reference herein in its entirety.

What is claimed is:

1. An imprint apparatus for forming a pattern on an imprint material on a substrate using a mold, comprising: a holder configured to hold the mold; and a deformation mechanism configured to deform the mold by applying a force to a side surface of the mold held by the holder, wherein the deformation mechanism includes: an actuator; a first member driven by the actuator; and a second member configured to press the side surface of the mold along with driving of the first member by the actuator.

2. The apparatus according to claim 1, wherein the deformation mechanism further includes a connecting portion configured to be able to switch between a connected state in which the first member and the second member are connected and a nonconnected state in which the first member and the second member are not connected.

3. The apparatus according to claim 2, wherein the connected state is a state in which when the actuator is driven, the first member and the second member can interlockingly press the side surface of the mold, and the nonconnected state is a state in which drive of the first member by the actuator does not act on the second member, and it is impossible to press the side surface of the mold.

4. The apparatus according to claim 3, wherein the connected state is a state in which even if the force is applied to the side surface of the mold held by the holder, no position deviation occurs between the first member and the second member.

5. The apparatus according to claim 2, further comprising a controller configured to control the actuator and the connecting portion.

6. The apparatus according to claim 5, wherein the controller controls the actuator and the connecting portion such that an output of the actuator is a first value, the second member contacts the side surface of the mold.

7. The apparatus according to claim 6, wherein the controller increases the output of the actuator from the first value when the output of the actuator is the first value, the second member and the side surface of the mold are in the nonconnected state, and the connecting portion is in the connected state, when the second member contacts the side surface of the mold, stops increasing the output of the actuator, switches the connecting portion to the nonconnected state, and returns the output of the actuator to the first value, and then switches the connecting portion to the connected state.

8. The apparatus according to claim 6, wherein the controller sets the output of the actuator to a second value larger than the first value to drive the first member when the mold is not loaded yet, the output of the actuator is the first value, and the connecting portion is in the nonconnected state,
switches the connecting portion to the connected state and returns the output of the actuator to the first value,
loads the mold in the state, causes the holder to hold the mold, and then increases the output of the actuator from the first value,
when the second member contacts the side surface of the mold, stops increasing the output of the actuator, switches the connecting portion to the nonconnected state, and returns the output of the actuator to the first value, and
then switches the connecting portion to the connected state.

9. The apparatus according to claim 7, wherein the deformation mechanism further includes a force sensor configured to measure the force given to the side surfaces of the mold, and the controller detects the contact using the force sensor.

10. The apparatus according to claim 2, wherein the holder includes a contact surface that comes into contact with the mold, the actuator is driven, above the holder, in a first direction parallel to the contact surface, the first member extends in a second direction crossing the contact surface and is connected to an output end of the actuator at one end and connected to the connecting portion at the other end, the second member extends in the first direction below the holder and is connected to the first member via the connecting portion at one end and configured to press the side surface of the mold on the other end side.

11. The apparatus according to claim 10, wherein the deformation mechanism further includes a fulcrum portion arranged on a wall surface crossing the contact surface in the holder, and the first member swings with respect to the fulcrum portion as a fulcrum in accordance with the driving of the actuator.

12. The apparatus according to claim 11, wherein the deformation mechanism further includes a parallel spring arranged between the holder and the second member, and the parallel spring can elastically be deformed in the first direction, and the second member is guided by the parallel spring and moved in the first direction in accordance with the swing of the first member.

13. The apparatus according to claim 2, wherein the holder includes a contact surface configured to hold the mold, and the deformation mechanism forms a linear motion mechanism in which the actuator, the first member, the connecting portion, and the second member are sequentially arranged in a first direction parallel to the contact surface toward the side surface of the mold.

14. The apparatus according to claim 2, wherein the second member includes an avoiding portion configured to absorb a distortion or position deviation in a direction parallel to the side surface of the mold.

15. An article manufacturing method comprising: forming a pattern on a substrate using an imprint apparatus defined in claim 1; and processing the substrate on which the pattern is formed in the forming, wherein an article is manufactured from the substrate processed in the processing.
